(19) United States
(12) Patent Application Publication
(10) Pub. No.: US 2011/0080781 A1
(43) Pub. Date: Apr. 7, 2011

(54) PHASE CHANGE MEMORY DEVICE AND CONTROL METHOD

(75) Inventor: Ludovic Goux, Hannut (BE)

(73) Assignees: NXP B.V., Eindhoven (NL); INTERUNIVERSITAIR MICROELEKTRONICA CENTRUM VZW, LEUVEN (BE)

(21) Appl. No.: 12/997,580

(22) PCT Filed: Jun. 9, 2009
(86) PCT No.: PCT/IB09/52438

§ 371 Date: Dec. 10, 2010

(30) Foreign Application Priority Data
Jun. 11, 2008 (EP) 08104377.0

(51) Int. Cl. G11C 11/21

(52) U.S. Cl. 365/163

(57) ABSTRACT

The present invention relates to a phase change memory device comprising a plurality of phase change memory cells, each cell comprising a phase change material (50) conductively coupled between a first electrode (44) and a second electrode (42) for applying a reset current pulse having a predefined polarity to the phase change material in a programming cycle of the phase change memory device; and a controller (70) coupled to the first electrode and the second electrode for reversing the polarity of the reset current pulse to be applied in a next number of programming cycles to the corresponding cell after the application of a first number of programming cycles to the corresponding cell. The present invention further relates to a method for controlling such a memory device.

The present invention relates to a phase change memory device comprising a plurality of phase change memory cells, each cell comprising a phase change material conductively coupled between a first electrode and a second electrode for applying a reset current pulse having a predefined polarity to the phase change material.

The present invention further relates to a method of controlling such a phase change memory.

Phase change memory (PCM) devices are attracting considerable attention in the field of semiconductor because they are capable of retaining data without requiring a permanent power supply. This makes PCM devices comparable to the widely adopted flash memory devices. However, because PCM devices have superior switching speeds compared to flash memory devices, PCM devices are widely considered to be more attractive because the higher switching speeds will allow for an increase in the processing performance of an integrated circuit comprising, or having access to, such a PCM device.

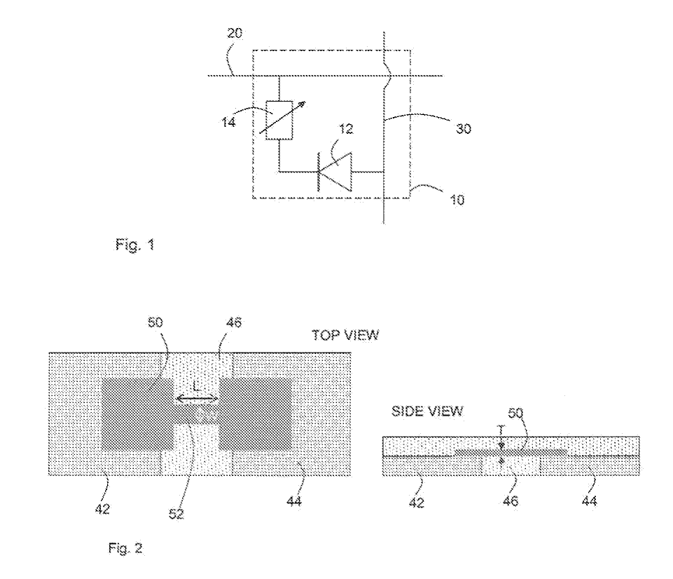

FIG. 1 depicts a schematic representation of a PCM cell 10. The PCM cell 10 typically comprises a diode element 12, which may be implemented using one or more enable transistors, coupled in series with a variable resistor 14 between a word line 20 and a bit line 30. The variable resistor comprises a chalcogenide material, which can be switched between an amorphous and a crystalline state, with the two states exhibiting a different intrinsic resistivity.

In a read mode of a memory device comprising PCM cells, this difference is exploited by determining the magnitude of a current flowing through the PCM cell, which is correlated to a predetermined binary value.

In a write mode, the variable resistor is exposed to a current pulse causing a phase change in the chalcogenide material. The high-resistive amorphous state, which is sometimes referred to as the reset state, is typically obtained by exposing the chalcogenide material to a current pulse having sufficient amplitude to cause the melting of the chalcogenide material, whereas the low-resistive crystalline state, which is sometimes referred to as the set state, is typically obtained by exposing the chalcogenide material to a current pulse having a lower amplitude but a longer duration than the current pulse required to bring the PCM cell in the reset state.

One of the problems associated with PCM devices is that it becomes progressively difficult to switch the chalcogenide material between the two states, leading to stuck-at-set and stuck-at-reset failures. Such failures, which are caused by a change in the material's resistance to the phase change, have for instance been reported by M. H. R. Lankhorst et al. in “Low-cost and nanoscale non-volatile memory concept for future silicon chips” in Nature Materials, 2005 (4), pages 865-866. Such failures typically start to appear after 10⁶-10⁹ switching cycles of the PCM cells.

It has been found that the pulse width applied to the PCM cell can have an influence of the lifetime of the chalcogenide material. For instance, S. Lai et al. in IEDM 2003, pages 10.1.1-10.1.4 have reported that in a vertical PCM cell using Ge₂Sb₂Te₅ as a chalcogenide material, the extent of the reset-switching degradation depends on the pulse width applied to the reset state of the PCM cell.

Similar behavior is observed in a line cell as disclosed by Lankhorst et al. An example of such as cell is shown in FIG. 2. The line cell has a first electrode 42 and a second electrode 44 separated by a dielectric 46, with a chalcogenide material 50 mounted on the electrodes. The chalcogenide material 50, which is a doped Sb—Te chalcogenide, comprises a line section 52 which has a predefined width W, length L and thickness T. Because the line section 52 has a higher resistance than the bulk chalcogenide sections 50, the phase change of the material may be confined to the line section 52, which allows for very rapid switching of such a line cell. This cell also demonstrates reset-switching degradation behavior, i.e. degradation behavior of the set state, which is directly related to the pulse width of the employed reset current pulse.

Performance degradation such as the aforementioned reset-switching degradation is undesirable for obvious reasons, and may prohibit PCM devices becoming the mainstream memory devices in e.g. CMOS integrated circuits because of question marks over the long-term reliability of PCM devices.

Lee et al. disclose in “A novel programming method to refresh a long-cycled phase change memory cell”, Proceedings of the Non-Volatile Semiconductor Memory Workshop, 2008 and 2008 International Conference on Memory Technology and Design. NVSMW/ICMTD 2008, pages 46-48 that the stuck-at-set behavior of a Ge₂Sb₂Te₅ chalcogenide material based PCM caused by the atomic migration of the chalcogenide material can be countered by periodically introducing remedial reverse polarity current pulses during programming cycles. This however has the drawback that device operation has to be temporarily interrupted to allow for execution of such a repair cycle during which these remedial pulses are applied.

The present invention seeks to provide a PCM having improved robustness against stuck-at-set and stuck-at-reset failures without compromising device performance.

The present invention further seeks to provide a method of controlling a PCM to improve its robustness against stuck-at-set and stuck-at-reset failures without compromising device performance.

According to a first aspect of the present invention, there is provided a phase change memory device comprising a plurality of phase change memory cells, each cell comprising a phase change material conductively coupled between a first electrode and a second electrode for applying a reset current pulse having a predefined polarity to the phase change material in a programming cycle of the phase change memory device and a controller coupled to the first electrode and the second electrode for reversing the polarity of the reset current pulse to be applied in a next number of programming cycles to the corresponding cell after the application of a first number of programming cycles to the corresponding cell.

The present invention has been based on the realization that the polarity of the reset pulses applied in different programming cycles may be reversed, thus obviating the need for applying remedial reverse polarity pulses in between programming cycles. This has the advantage that the memory device of the present invention can be operated in a continuous manner without the need to introduce a repair cycle. The memory device of the present invention may be a stand-alone device or may be embedded in an integrated circuit.

The number of cycles may be chosen such that the polarity of the reset current pulse is only reversed when there is reason to assume that degradation effects in the chalcogenide material may have progressed to a point where the guaranteed correct functioning of the PCM cell has reached its duration limit. For instance, this number may be obtained through simulation. In an embodiment, the phase change memory further comprises a counter coupled to the controller for counting the number of reset current pulses applied to a conductor coupled to the first electrode, wherein the controller is arranged to reverse the polarity of the reset current pulse when said number reaches this predefined value. This counter may for instance count every instance at which the PCM cell is addressed.

Alternatively, the counter may count every instance at which a reset current pulse is applied to a conductor such as a bit line, which is typically shared by a plurality of PCM cells. This does not yield an accurate account of the number of times the PCM cell under monitoring has been reset. However, this is not necessarily a disadvantage because the reversal of the polarity of the reset current pulse will be applied more conservatively, i.e. well before the chalcogenide material approaches its degradation limit, thus reducing the risk of the occurrence of a PCM cell failure.

The degradation limit of the chalcogenide material may also be expressed in terms of the resistance of the material. It is known that degradation of the chalcogenide material can be monitored by a drop in its resistance. Therefore, the phase change memory may further comprise an arrangement coupled to the controller for measuring the resistance of the phase change material, wherein the controller is arranged to reverse the polarity of the reset current pulse when the measured resistance of the set state of the phase change material drops below a predefined value, which typically is a lowest value at which error-free switching of the PCM cell can be guaranteed. This measured resistance may be the set state resistance or the reset state resistance of the memory cell, and is typically measured following the application of a set or reset pulse to the cell.

In an alternative embodiment, the controller is arranged to reverse the polarity of the reset current pulse after each write cycle of the corresponding cell. This obviates the need for degradation monitoring hardware on the PCM device.

In a preferred embodiment, the controller is arranged to apply a bipolar reset current pulse to the phase change memory cells, which means that the periodic polarity reversal is applied within every programming cycle. This has the advantage that no monitoring hardware is required to monitor the degradation of the set state, because the use of a bipolar pulse substantially reduces the rate of degradation.

The PCM device of the present invention may be incorporated in any suitable electronic device. Such an electronic device would benefit from the increased lifetime of the PCM device of the present invention.

In accordance with another aspect of the present invention, there is provided a method of controlling a phase change memory device comprising a plurality of phase change memory cells, each cell comprising a phase change material conductively coupled between a first electrode and a second electrode, the method comprising applying a reset current pulse having a predefined polarity to the phase change material during a programming cycle of the phase change memory cell; and reversing the polarity of the reset current pulse of a next number of programming cycles after a number of programming cycles. This extends the lifetime of the phase change memory device as previously explained.

The method may further comprise counting the number of reset current pulses applied to a conductor coupled to the first electrode, wherein said reversing step is performed after said number reaches a predefined value in order to only reverse the polarity when necessary. Said counting step may comprise counting the number of programming cycles applied to the phase change memory cell to give a more accurate indication of when the polarity of the reset current pulse should be reversed.

Alternatively, the method may further comprise measuring the resistance of the phase change material of the phase change memory cell, wherein said reversing step is performed when the measured resistance of a crystalline or amorphous state of the phase change material drops below a predefined value. The resistance of the phase change material is another indicator of the degradation state of the chalcogenide material, and may be used to timely change the polarity of the reset current pulse.

In another embodiment, said reversing step is performed after each write cycle, which obviates the need to monitor the degradation state of the chalcogenide material.

Embodiments of the invention are described in more detail and by way of non-limiting examples with reference to the accompanying drawings, wherein:

FIG. 1 schematically depicts the concept of a PCM cell;

FIG. 2 schematically depicts a known PCM cell;

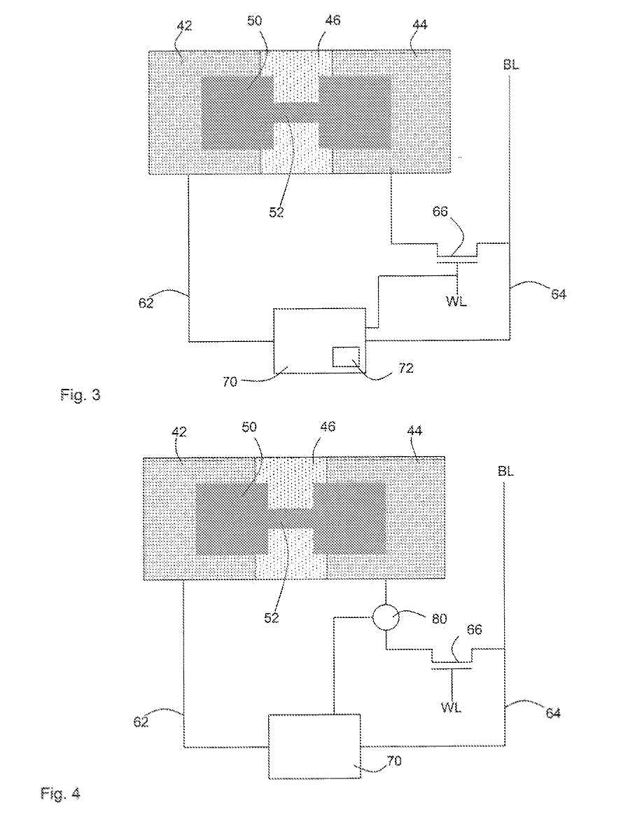

FIG. 3 schematically depicts an embodiment of a PCM of the present invention;

FIG. 4 schematically depicts another embodiment of a PCM of the present invention;

FIG. 5a-b show non-limiting examples of reset current pulse shapes;

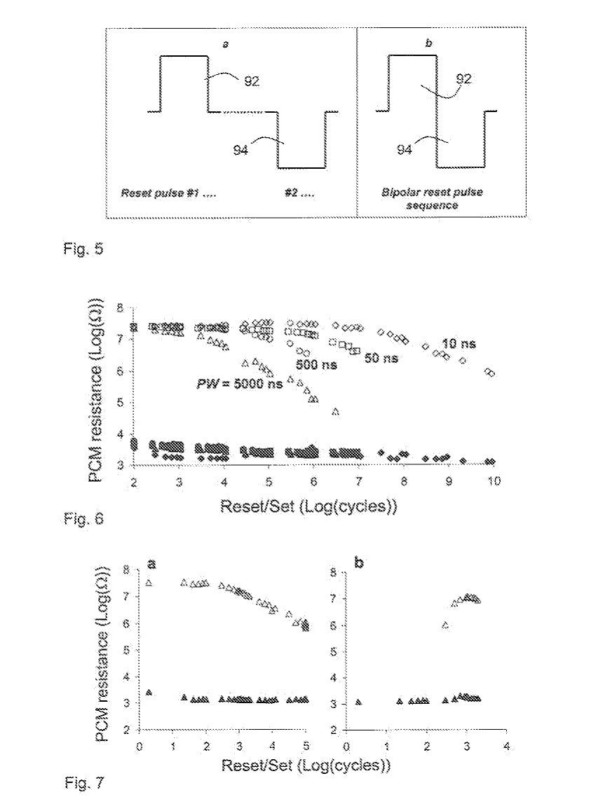

FIG. 6 depicts the effect of the pulse width of the reset current pulse on the degradation characteristics of a PCM cell; and

FIG. 7a-b depict the effect of periodic polarity reversal of the reset current pulse on the degradation characteristics of a PCM cell.

It should be understood that the Figures are merely schematic and are not drawn to scale. It should also be understood that the same reference numerals are used throughout the Figures to indicate the same or similar parts.

FIG. 3 shows a first embodiment of a PCM device in accordance with the present invention. By way of non-limiting example, the PCM line cell of FIG. 2 is used to demonstrate the principles of the present invention. However, it will be understood that the specific layout of the PCM cells is not of critical importance to the teachings of the present invention, and that other PCM cell architectures may be equally feasible.

The first electrode 42 of a PCM cell of the PCM device of the present invention is typically coupled to a first conductor 62 external to the PCM cell, whereas the second electrode 44 of a PCM cell of the PCM device of the present invention is typically coupled to a second conductor 64 external to the PCM cell. The first conductor 62 may be a first supply rail, whereas the second conductor 64 may be a second supply rail.

In known PCM devices, the first supply rail is typically kept at a fixed potential, e.g. ground, whereas the second supply rail is used as a bit line BL for periodically providing the PCM cell with a current pulse either to establish the state of the chalcogenide material 50 in a read mode or to change the state of the chalcogenide material 50 in a write mode of the PCM device. Such current pulses may be generated in any suitable way.

For instance, in case of an enable transistor 66 coupled between the bit line 64 and the second electrode 44, the word line WL coupled to the gate of the enable transistor 66 may be provided with a pulse of low amplitude, with the bit line BL being simultaneously provided with a high amplitude current pulse to rewrite the PCM cell. In this case, the amount of current to be applied to the chalcogenide material 50 is varied by varying the amplitude of the current pulse applied to the bit line BL.

Alternatively, the bit line BL may be provided with a pulse of low amplitude, with the word line WL being simultaneously provided with a high amplitude current pulse to rewrite the PCM cell. In this case, the amount of current to be applied to the chalcogenide material 50 is varied by varying the conductivity of the enable transistor 66. It will be appreciated that other drive schemes, which may for instance be combinations of the above drive schemes are equally feasible.

One aspect that the known drive schemes have in common with each other is that the current flow through the chalcogenide material 50 has the same direction in each programming cycle of the PCM cell, because the potential difference between the first conductor 62 and the second conductor 64 has a fixed sign. For instance, if the first conductor 62 is a supply rail connected to ground and the second conductor 64 is a supply rail connected to a positive voltage source, e.g. V_{dd}, the current through the PCM cell will always flow from the second electrode 44 to the first electrode 42. This causes the migration of ionized chalcogenide material 50, which, as has been discovered by the present inventors, contributes to the occurrence of stuck-at-set and stuck-at-reset faults for the PCM cell. It is pointed out that this is also the case for the reverse polarity reset pulses disclosed in the paper by Lee et al., because these reverse polarity pulses are not applied during programming cycles but in between programming cycles, as previously explained.

The PCM device of the present invention further comprises a controller 70, which is arranged to periodically reverse the direction of the current through the PCM cell at least during a programming cycle in order to reverse the migration direction of the chalcogenide material 50, thereby at least partially reversing degradation effects in the chalcogenide material 50. For instance, the controller 70 may be arranged to periodically reverse the polarity of the voltage across the first conductor 62 and the second conductor 64. This may be achieved in any suitable way. For instance, the first conductor 62 may be periodically reconnected to V_{dd} instead of ground, with the second conductor 64 at the same time being reconnected to ground instead of V_{dd}. The controller 70 may include the driver circuitry (not shown) for the PCM cells of the PCM device of the present invention. Alternatively, the controller 70 is only arranged to provide the first conductor 62 and the second conductor 64 with a predefined potential, with the PCM device further comprising driver circuitry (not shown) for shaping the predefined potentials into suitable current pulses. The controller 70 may comprise a counter 72 for counting the number of times the word line WL of the PCM cell has been activated. Alternatively, the counter 72 may be arranged to count the number of times the bit line BL has been activated. The latter does not necessarily mean that a monitored PCM cell has been rewritten, since the bit line BL is typically shared by a number of PCM cells, e.g. 4, 8 16 or 32 PCM cells, which are only rewritten when the word line WL of the monitored PCM cell is simultaneously activated such that the enable transistor 66 becomes enabled and the chalcogenide material 50 is exposed to a current defined by the potential difference between the first conductor 62 and the bit line BL.

Alternatively, the counter 72 may count the number of times both the BL and the WL of a given cell are simultaneously addressed, which may for instance be realized by making the counter 72 responsive to an AND gate (not shown) which has its respective inputs coupled to the BL and WL.

The counter 72, which may form a part of the controller 70 or may be external to the controller 70, is typically arranged to compare the counted number of activations of the word line WL and/or the bit line BL with a predefined number, and to notify the controller 70 when the predefined number has been met. The predefined number is typically obtained through simulation to give an indication after how many reset cycles the chalcogenide material 50 is beginning to exhibit a lowered resistance in its reset state, such that the reversal of the reset pulse polarity is applied before resistance of amorphous state of the chalcogenide material 50 drops below a critical value, i.e. a value at which the risk of stuck-at faults becomes non-negligible. The controller 70 uses this trigger to reverse the polarity of the reset pulses, i.e. the pulses to bring the chalcogenide material 50 into its reset state, applied in the next series of programming cycles.

FIG. 4 shows an alternative embodiment of the PCM device of the present invention, in which the counter 72 is replaced by a resistance meter 80 to obtain an indication of the resistance of the chalcogenide material 50. In FIG. 4, the resistance meter 80 is placed between the enable transistor 66 and the second electrode 44 by way of non-limiting example only. Placement of the resistance meter 80 between the enable transistor 66 and the bit line BL or in the bit line BL is equally feasible.

The resistance meter 80 is arranged to signal the controller when the resistance of the chalcogenide material 50 drops below a predefined threshold, thus indicating that the chalcogenide material 50 has reached a state of degradation at which reset pulse polarity reversal is required to prevent the occurrence of stuck-at-set faults. The resistance meter 80 may be implemented in any suitable way.

The controller 70 may be configured to apply the reverse polarity reset pulses during subsequent programming cycles until the resistance meter 80 signals that the resistance of the chalcogenide material 50 has recovered to a further predefined value, which also may have been obtained through simulation. This further predefined value may alter during the lifetime of the PCM device to take into account ageing effects and/or irreversible degradation effects in the chalcogenide material 50. To this end, the resistance meter 80 may include, or may be responsive to a counter such as counter 72 to select the appropriate further predefined value based on the number of executed programming cycles.

In an embodiment, the controller 70 of FIG. 4 is arranged to subject one or more PCM cells to a burst of remedial current pulses in between programming cycles having a reversed polarity compared to the programming cycle reset current pulse. The controller 70 is responsive to the resistance meter 80 to terminate the application of the restoration pulses as soon as the resistance of the chalcogenide material 50 has reached a known good value, e.g. the further predefined value as discussed earlier.

The PCM device of FIGS. 3 and 4 may comprise one or more controllers 70 for monitoring the PCM cells. In case of a plurality of controllers 70, the controllers 70 may be arranged such that the polarity of the reset current pulses applied to any PCM cell is reversed as soon as one of the controllers 70 is triggered to reverse said polarity.

In a further embodiment, the counter 72 or the resistance meter 80 may be omitted, and the controller 70 may be arranged to change the polarity of the reset current pulse after every cycle. This is shown in FIG. 5a, in which a positive reset current pulse 92 is followed by a negative reset current pulse 94 in a subsequent write cycle. Alternatively, as shown in FIG. 5b, a positive reset current pulse 92 and a negative reset current pulse 94 may be combined into a single bipolar reset current pulse. The bipolar pulse shape has the advantage that the net migration of chalcogenide material 50 during a programming cycle is effectively cancelled out, which increases the lifetime of the PCM device without requiring the reversal of the polarity of reset current pulses after a number of programming cycles, which simplifies the design of the PCM device and reduces area overhead required for the hardware dedicated to the lifetime extension of the device.

FIG. 6 shows the effect of the reset pulse width on the resistance of a line cell as shown in FIG. 2, wherein the electrodes 42 and 44 are tungsten electrodes, with the chalcogenide material 50 being a doped-SbTe chalcogenide, with the line 52 having dimensions T=20 nm, W=100 nm and L=450 nm. As can be seen from FIG. 6, the degradation rate of the SbTe chalcogenide reset state (open symbols) depends on the applied reset pulse width. It is emphasized that the resistance of the set state also decreases as a result of such degradation. It is clearly demonstrated that minimizing the pulse width of the reset pulse has a beneficial effect on the endurance of the reset state of the PCM cell. It was found that the endurance of the reset state was largely independent of the amplitude of the applied current.

FIG. 7a shows a reset/set endurance plot of the same PCM cell using a pulse width of 10 μs which ends in a stuck-at set failure after addressing the cell with a reset pulse 10⁵ times. It is clear that the reset state resistance (open symbols) significantly reduces after exposure to several reset current pulses, thus indicating a change in the structure of the chalcogenide material 50. FIG. 7b shows the partial recovery of the reset state resistance (open symbols) after the application of a few hundred restoration pulses to the stuck-at-set cell, thus indicating that the reset-switching failure of the cell is reversible. The fact that the recovery is only partial indicates that the degradation process cannot be solely attributed to migration of the chalcogenide material 50.

It has been demonstrated that the life time of a PCM cell can be extended to beyond 10¹⁰ reset cycles by application of the teachings of the present invention. Preferably, the pulse width of the reset current pulses applied in the programming cycles of the PCM device should not exceed 50 ns because such short pulses reduce the degradation rate of the PCM cells, as shown in FIG. 6. More preferably, the pulse width of the reset current pulses should not exceed 20 ns or even 10 ns because this further reduces the degradation rate of the PCM cells. The combination of the periodic polarity reversal of the reset current pulses with a pulse width of the reset current pulses that does not exceed the aforementioned preferred pulse width values is particularly advantageous because this has been found to increase the lifetime of a PCM cell by at least a factor 2.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The invention can be implemented by means of hardware comprising several distinct elements. In the device claim enumerating several means, several of these means can be embodied by one and the same item of hardware. The mere fact that certain measures are recited in mutually different dependent claims does not indicate that a combination of these measures cannot be used to advantage.

1. A phase change memory device comprising:
a plurality of phase change memory cells, each cell comprising a phase change material conductively coupled between a first electrode and a second electrode for applying a reset current pulse having a predefined polarity to the phase change material in a programming cycle of the phase change memory device; and
a controller coupled to the first electrode and the second electrode for reversing the polarity of the reset current pulse to be applied in a next number of programming cycles to the corresponding cell after the application of a first number of programming cycles to the corresponding cell.

2. A phase change memory according to claim 1, further comprising a counter coupled to the controller for counting the number of reset current pulses applied to a conductor coupled to the first electrode, wherein the controller is arranged to reverse the polarity of the reset current pulse when said number reaches a predefined value.

3. A phase change memory according to claim 2, wherein the counter is arranged to count the number of resets of the corresponding phase change memory cell.

4. A phase change memory according to claim 1, further comprising an arrangement coupled to the controller for measuring the resistance of the phase change material, wherein the controller is arranged to reverse the polarity of the reset current pulse when the measured resistance of a crystalline or amorphous state of the phase change material drops below a predefined value.

5. A phase change memory according to claim 4, wherein the controller is arranged to apply the reverse polarity pulses until the measured resistance of the crystalline or amorphous state of the phase change material has recovered to a further predefined value.

6. A phase change memory according to claim 1, wherein the controller is arranged to reverse the polarility of the reset current pulse after each write cycle of the corresponding cell.

7. A phase change memory device comprising:
a plurality of phase change memory cells, each cell comprising a phase change material conductively coupled between a first electrode and a second electrode for applying a reset current pulse having a predefined polarity to the phase change material in an programming cycle of the phase change memory device; and
a controller coupled to the first electrode and the second electrode for applying a bipolar reset current pulse to the phase change memory cells.

8. A phase change memory according to claim 1, wherein the phase change memory cell comprises an enable transistor coupled between the first electrode and a bit line of the phase change memory, said enable transistor having a gate coupled to a word line of the phase change memory.

9. An integrated circuit comprising a phase change memory device according to claim 1.

10. A method of controlling a phase change memory device comprising a plurality of phase change memory cells, each cell comprising a phase change material conductively coupled between a first electrode and a second electrode, the method comprising:
applying a reset current pulse having a predefined polarity to the phase change material during a programming cycle of the phase change memory cell; and
reversing the polarity of the reset current pulse applied during a programming cycle after a number of programming cycles.

11. A method according to claim 10, further comprising:
counting the number of reset current pulses applied to a conductor coupled to the first electrode, wherein said reversing step is performed after said number reaches a predefined value.

12. A method according to claim 11, wherein said counting step comprises counting the number of programming cycles applied to the phase change memory cell.

13. A method according to claim 10, further comprising measuring the resistance of the phase change material of the phase change memory cell, wherein said reversing step is performed when the measured resistance of a crystalline or amorphous state of the phase change material drops below a predefined value.

14. A method according to any of claims 13, further comprising applying the reverse polarity reset pulses until said measured resistance has recovered to a further predefined value.

15. A method according to claim 10, wherein said reversing step is performed after each programming cycle.
